(19) United States
(12) Patent Application Publication
(10) Pub. No.: US 2025/0169136 A1
(43) Pub. Date: May 22, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Fu-Hsiang SU, Zhubei city (TW); Je-Wei HSU, Hsinchu City (TW); Ping-Chun WU, Hsinchu City (TW); Chia-Hao KUO, Taoyuan City (TW); Shih-Hsun CHANG, Hsinchu (TW)

(73) Assignee: Taiwan Semiconductor Manufacturing Company, Ltd., Hsinchu (TW)

(21) Appl. No.: 18/512,935

(22) Filed: Nov. 17, 2023

(51) Int. Cl. H01L 29/40; H01L 21/285; H01L 29/06; H01L 29/417; H01L 29/423; H01L 29/45; H01L 29/66; H01L 29/775

(52) U.S. Cl. CPC H10D 64/01; H01L 21/28518; H10D 30/014; H10D 30/43; H10D 30/6729; H10D 30/6735; H10D 62/121; H10D 64/015; H10D 64/021; H10D 64/62

(57) ABSTRACT

A method for forming a semiconductor device structure includes forming nanostructures over a substrate. The method also includes forming a gate structure wrapped around the nanostructures. The method also includes forming source/drain epitaxial structures over opposite sides of the nanostructures. The method also includes forming an interlayer dielectric structure over the source/drain epitaxial structures. The method also includes etching the interlayer dielectric structure to form an opening exposing the source/drain epitaxial structures. The method also includes depositing a first spacer layer over sidewalls of the interlayer dielectric structure in the opening. The method also includes forming a silicide structure over the source/drain epitaxial structures. The method also includes forming a bottom contact structure over the silicide structure. The method also includes depositing a second spacer layer over the first spacer layer. The method also includes forming an upper contact structure over the first contact structure.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1F are perspective representations of various stages of forming a semiconductor device structure, in accordance with some embodiments of the disclosure.

FIGS. 1G, 1G-1, 1H, 1H-1, 1I-1L are cross-sectional representations of various stages of forming a semiconductor device structure, in accordance with some embodiments of the disclosure.

FIGS. 2A-2C are cross-sectional representations of various stages of forming a semiconductor device structure, in accordance with some embodiments of the disclosure.

FIGS. 3A-3D are cross-sectional representations of various stages of forming a semiconductor device structure, in accordance with some embodiments of the disclosure.

FIGS. 4A-4C are cross-sectional representations of various stages of forming a semiconductor device structure, in accordance with some embodiments of the disclosure.

FIGS. 5A, 5B are top views of various stages of forming a semiconductor device structure, in accordance with some embodiments of the disclosure.

FIGS. 5A-1, 5A-2, 5B-1, 5B-2, 5C, 5C-1, 5D, 5D-1 are cross-sectional representations of various stages of forming a semiconductor device structure, in accordance with some embodiments of the disclosure.

FIG. 6A is a top view of forming a semiconductor device structure, in accordance with some embodiments of the disclosure.

FIGS. 6A-1, 6A-2, 6B, 6B-1, 6C, 6C-1 are cross-sectional representations of various stages of forming a semiconductor device structure, in accordance with some embodiments of the disclosure.

FIG. 7A is a top view of forming a semiconductor device structure, in accordance with some embodiments of the disclosure.

FIGS. 7A-1, 7A-2, 7B, 7B-1, 7C, 7C-1 are cross-sectional representations of various stages of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, forksheet structures, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments for forming a semiconductor device structure are provided. The method for forming the semiconductor device structure may include depositing multiple spacer layers during forming the source/drain contact structure. The profile of the source/drain contact structure may be modified by the multiple dielectric layers. With wider bottom source/drain contact structure, the silicide structure may be larger, and the resistance may be lowered. With narrower upper source/drain contact structure, the capacitance may be lowered.

The semiconductor device structure may include various active devices. For example, the semiconductor device structure may include gate all around (GAA) structures. The semiconductor device structure may also include channel structures such as nanosheet structures, forksheet structures, and CFET structures. The semiconductor device structure may also include FinFET structures, or Si and SiGe planar transistors.

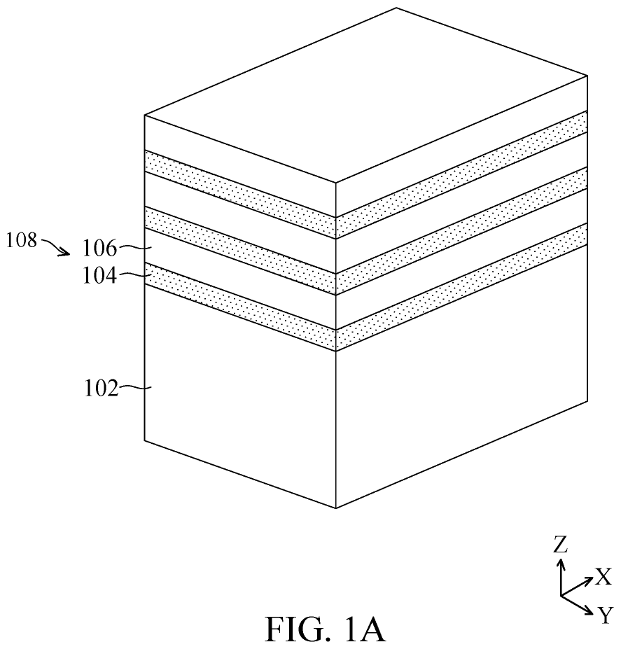

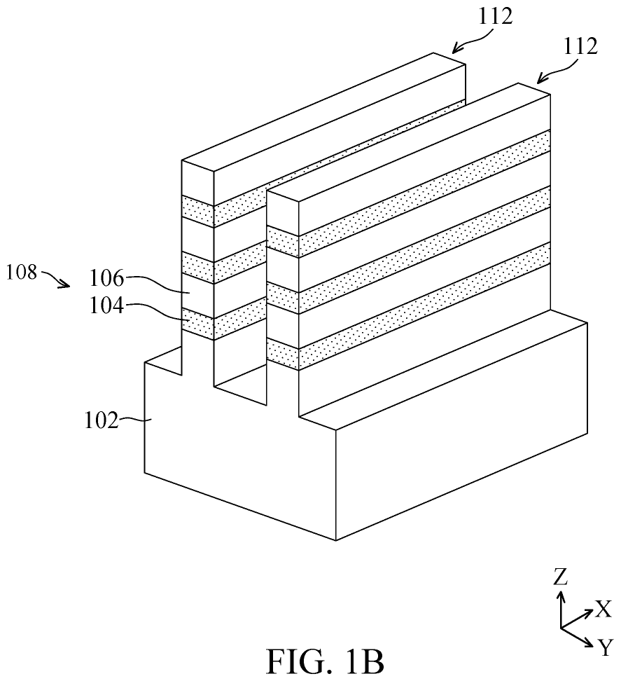

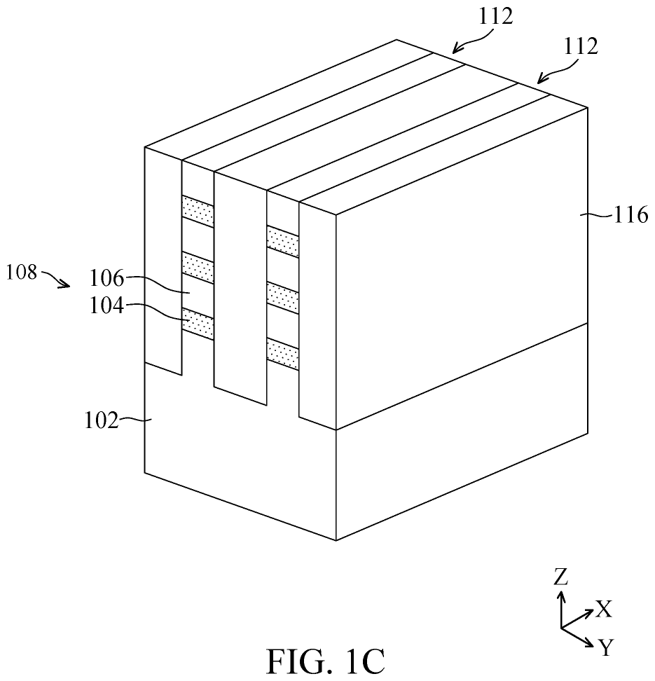

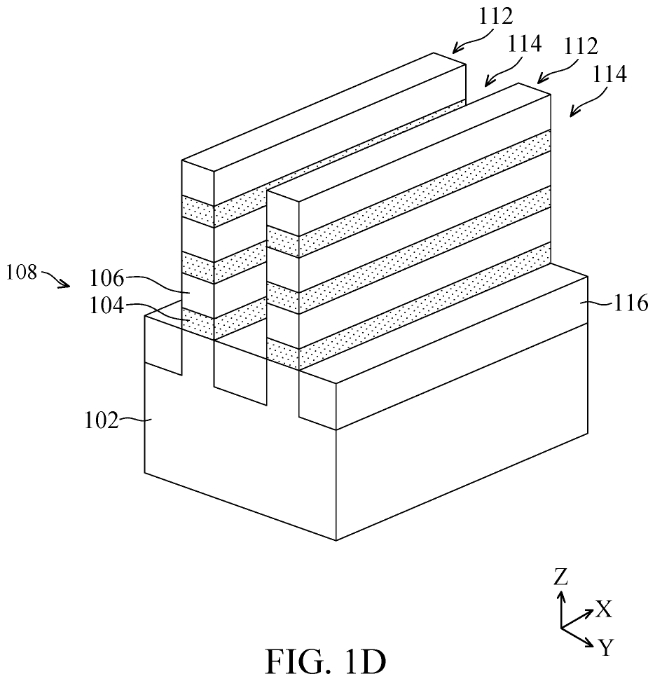

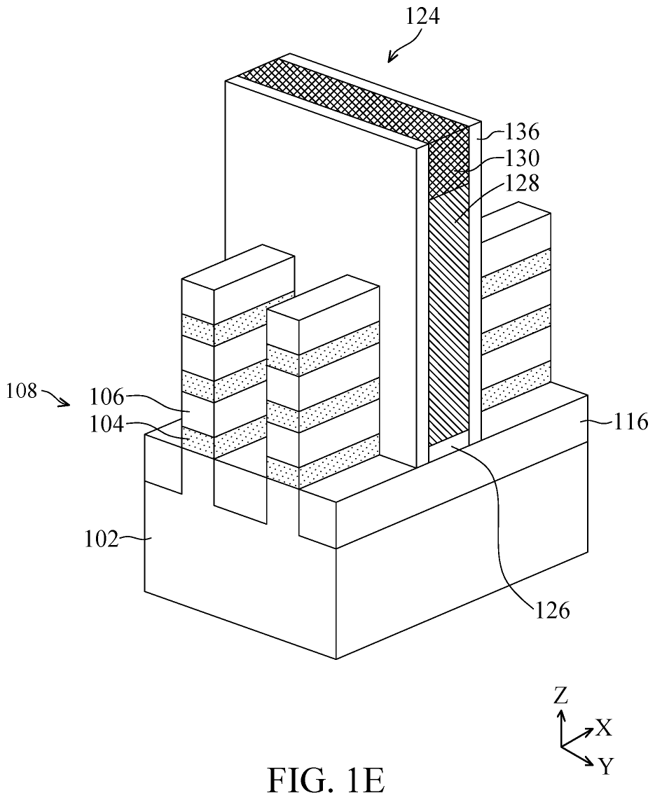

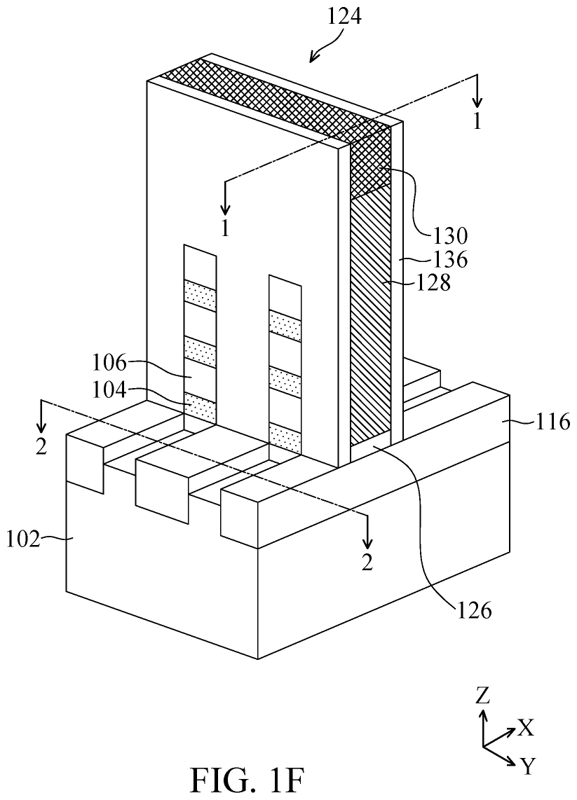

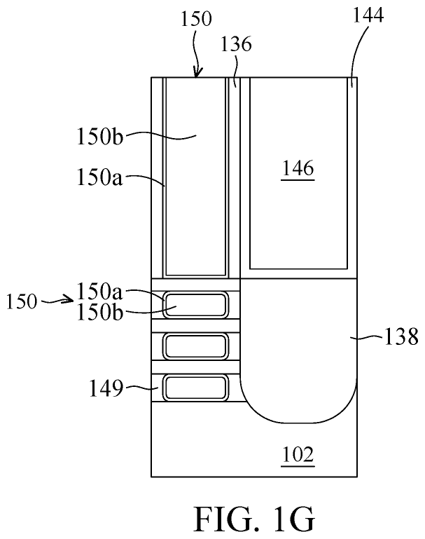

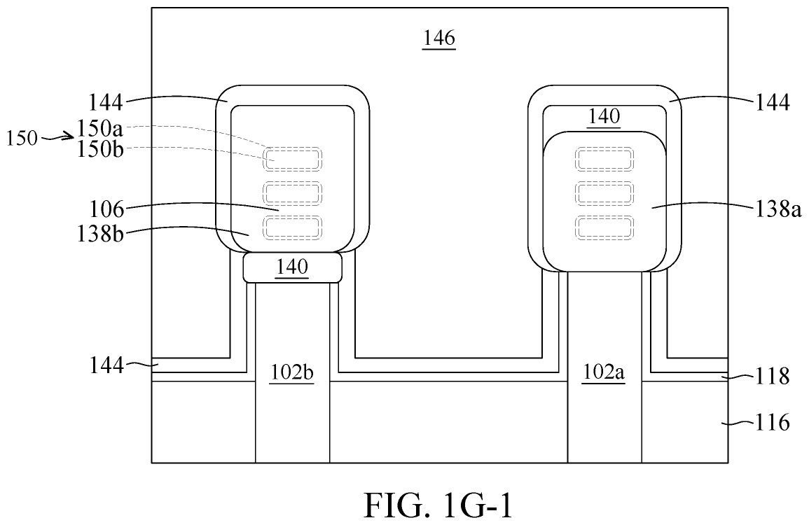

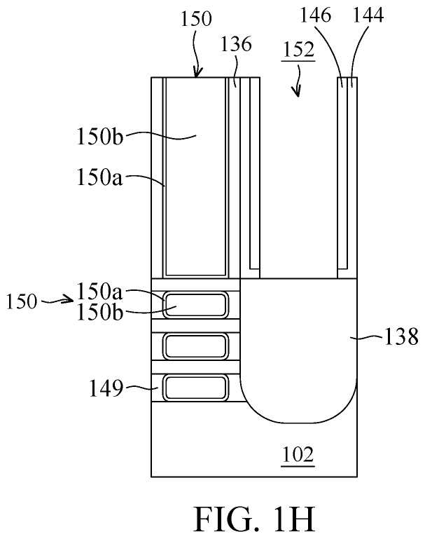

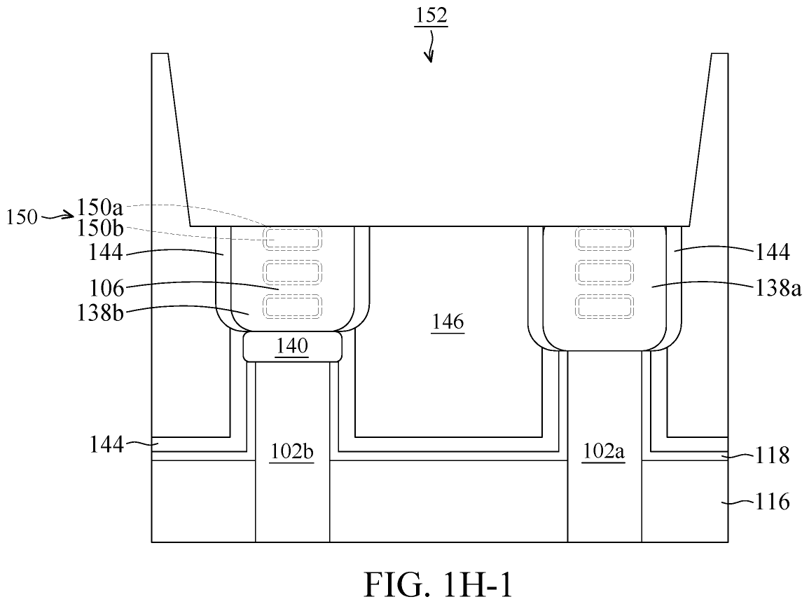

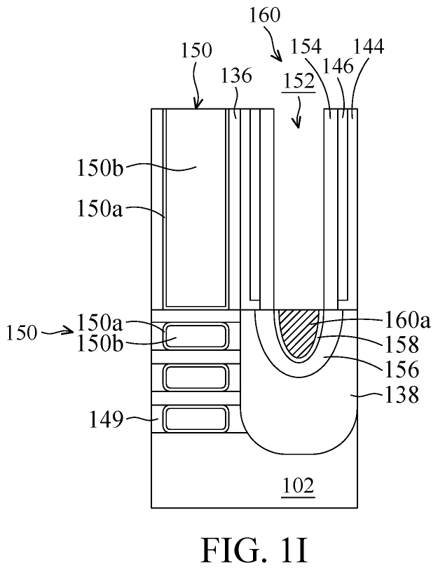

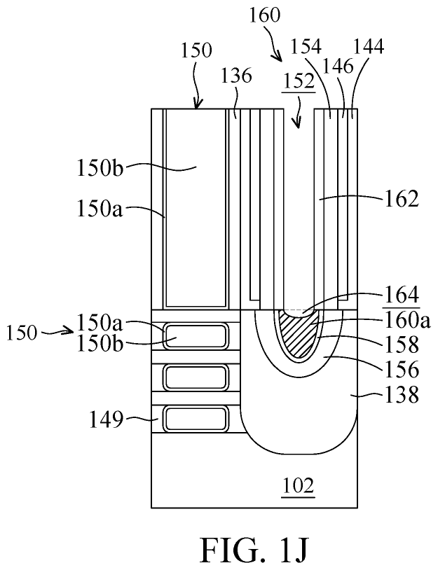

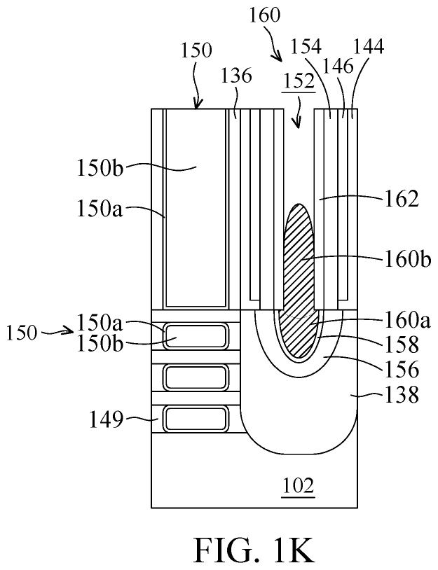

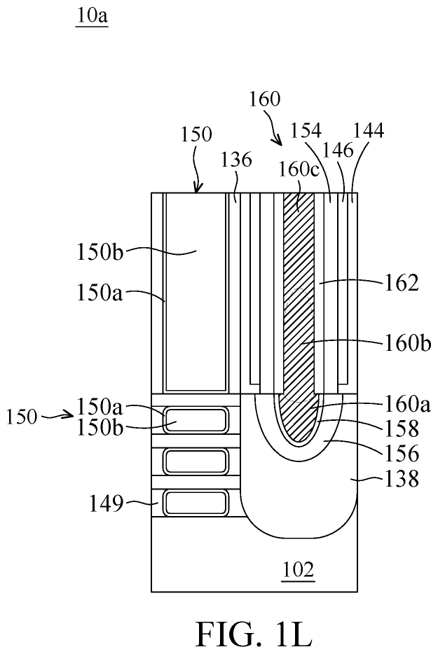

The semiconductor device structure 10a may be a nanostructure transistor. FIGS. 1A-1F are perspective representations of various stages of forming a semiconductor device structure 10a, in accordance with some embodiments of the disclosure. FIGS. 1G, 1G-1, 1H, 1H-1, 1I-1L are cross-sectional representations of various stages of forming a semiconductor device structure, in accordance with some embodiments of the disclosure. FIGS. 1G, 1H and 1I-1L show cross-sectional representations taken along line 1-1 in FIG. 1F. FIGS. 1G-1 and 1H-1 show cross-sectional representations taken along line 2-2 in FIG. 1F.

A semiconductor stack 108 including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, alloy semiconductor materials, or a combination thereof. Examples of the elementary semiconductor materials may include, but are not limited to, crystal silicon, polycrystalline silicon, amorphous silicon, germanium, diamond, or a combination thereof. Examples of the compound semiconductor materials may include, but are not limited to, silicon carbide, gallium nitride, gallium arsenic, gallium phosphide, indium phosphide, indium arsenide, indium antimonide, or a combination thereof. Examples of the alloy semiconductor materials may include, but are not limited to, SiGe, GaAsP, AlInAs, AlGaAs, GaInAs, GaInP, GaInAsP, or a combination thereof. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack 108, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIGS. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure may be formed over the semiconductor stack 108. The mask structure may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

After the first semiconductor material layers 104 and the second semiconductor material layers 106 are formed as the semiconductor stack 108 over the substrate 102, the semiconductor stack 108 is patterned to form fin structures 112 using the mask structure as a mask layer, as shown in FIG. 1B in accordance with some embodiments. The fin structures 112 may include base fin structures and the semiconductor stack 108, including the first semiconductor material layers 104 and the second semiconductor material layers 106, formed over the base fin structure.

The patterning process may include forming a mask structure over the first semiconductor material layers 104 and the second semiconductor material layers 106 and etching the semiconductor stack 108 and the underlying substrate 102 through the mask structure.

The patterning process of forming the fin structures 112 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 112 are formed, a liner layer may be formed over the fin structures 112 and in the trenches between the fin structures 112. The liner layer may be conformally formed over the substrate 102, the fin structures 112, and the mask structure covering the fin structures 112. A liner layer may be used to protect the fin structures 112 from being damaged in the following processes (such as an anneal process or an etching process). The liner layer may be made of silicon nitride. The liner layer may be formed using thermal oxidation, a CVD process, an atomic layer deposition (ALD) process, an LPCVD process, a plasma enhanced CVD (PECVD) process, an HDPCVD process, a flowable CVD (FCVD) process, another applicable process, or a combination thereof.

Next, an isolation material 116 is then filled into the trenches between the fin structures 112 and over the liner layer, as shown in FIG. 1C in accordance with some embodiments. The isolation material 116 may be made of silicon oxide, silicon nitride, silicon oxynitride (SiON), fluoride-doped silicate glass (FSG), other low-k dielectric materials, or a combination thereof. The isolation material 116 may be deposited by a deposition process, such as a chemical vapor deposition (CVD) process (e.g. a flowable CVD (FCVD) process), a spin-on-glass process, or another applicable process.

Next, the hard mask layer over the fin structures 112 may be removed, and the pad layer over the fin structures 112 may be exposed. The hard mask layer may be removed by performing a planarization process such as a chemical mechanical polishing (CMP) process.

Next, the isolation material 116 is etched back using an etching process, and an isolation structure 116 is formed surrounding the base fin structure, as shown in FIG. 1D in accordance with some embodiments. The etching process may be used to remove the top portion of the isolation material 116. The pad layer over the fin structure 112 may be removed in the etching process. As a result, the semiconductor stack 108 may be exposed. The isolation structure 116 may be a shallow trench isolation (STI) structure 116. The isolation structure 116 may be configured to electrically isolate active regions such as fin structures 112 of the semiconductor structure 10a and prevent electrical interference and crosstalk.

Next, a protection layer 118 may be formed over the isolation structure 116 and the substrate 102 (not shown). The protection layer 118 may be made of a dielectric material such as silicon oxide. The protection layer 118 may be formed by CVD, PVD, ALD, spin-on coating, or another applicable process.

Next, a dummy gate structure 124 is formed over and across the fin structures 112, as shown in FIG. 1E in accordance with some embodiments. The dummy gate structure 124 may be used to define the source/drain regions and the channel regions of the resulting semiconductor structure 10a. The dummy gate structure 124 may include a dummy gate dielectric layer 126 and a dummy gate electrode layer 128. The dummy gate dielectric layer 126 and the dummy gate electrode layer 128 may be replaced by the following steps to form a real gate structure with a high-k dielectric layer and a metal gate electrode layer.

The dummy gate dielectric layer 126 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 126 may be formed by an oxidation process (e.g., a dry oxidation process, or a wet oxidation process), a chemical vapor deposition process, other applicable processes, or a combination thereof. Alternatively, the dummy gate dielectric layer 126 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 128 may include polycrystalline-silicon (poly-Si), poly-crystalline silicon-germanium (poly-SiGe), other applicable materials, or a combination thereof. The dummy gate electrode layer 128 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Next, a hard mask layer 130 is formed over the dummy gate structure 124, as shown in FIG. 1E in accordance with some embodiments. The hard mask layer 130 may include multiple layers, such as an oxide layer and a nitride layer. In some embodiments, the oxide layer includes silicon oxide, and the nitride layer includes silicon nitride.

The formation of the dummy gate structure 124 may include conformally forming a dielectric material as the dummy gate dielectric layer 126. Afterwards, a conductive material may be formed over the dielectric material as the dummy gate electrode layer 128. The hard mask layer 130, including the oxide layer and the nitride layer, may be formed over the conductive material. Next, the dielectric material and the conductive material may be patterned and etched through the hard mask layer 130 to form the dummy gate structure 124, as shown in FIG. 1E in accordance with some embodiments. The dummy gate dielectric layer 126 and the dummy gate electrode layer 128 may be etched by a dry etching process. After the etching process, the first semiconductor material layers 104 and the second semiconductor material layers 106 may be exposed at opposite sides of the dummy gate structure 124.

Next, a conformal dielectric layer is formed over the substrate 102 and the dummy gate structure 124, and then an etching process is performed. A pair of gate spacer layers 136 is formed over opposite sidewalls of the dummy gate structure 124, as shown in FIG. 1E in accordance with some embodiments

The gate spacer layers 136 may be multi-layer structures formed by different materials with different etching selectivity. The gate spacer layers 136 may be made of silicon oxide, silicon nitride, silicon oxynitride, dielectric materials, or a combination thereof. The gate spacer layers 136 may be formed by a chemical vapor deposition (CVD) process, a spin-on-glass process, or another applicable process.

After the gate spacer layers 136 are formed, the first semiconductor material layers 104 and the second semiconductor material layers 106 of the fin structures 112 not covered by the dummy gate structure 124 and the gate spacer layers 136 are etched to form the source/drain opening beside the dummy gate structure 124, as shown in FIG. 1F in accordance with some embodiments. A recess may be formed in the isolation structure 116 when etching the first semiconductor material layers 104 and the second semiconductor material layers 106 of the fin structures 112. The protection layer 118 not covered by the dummy gate structure 124 and the gate spacer layers 136 may be consumed during the etching process.

The fin structures 112 may be recessed by performing a number of etching processes. That is, the first semiconductor material layers 104 and the second semiconductor material layers 106 of the fin structures 112 may be etched in different etching processes. The etching process may be a dry etching process or a wet etching process. The fin structures 112 may be etched by a dry etching process.

Next, the first semiconductor material layers 104 may be laterally etched from the source/drain opening to form recesses. The outer portions of the first semiconductor material layers 104 may be removed, and the inner portions of the first semiconductor material layers 104 under the dummy gate structure 124 and the gate spacer layers 136 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer 149 may be formed in the recess. The inner spacer 149 may provide a barrier between subsequently formed source/drain epitaxial structures and gate structure. The inner spacer 149 may be made of a dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer 149 may be formed using a deposition process. The deposition process may include a CVD process (such as LPCVD, PECVD, SACVD, or FCVD), an ALD process, another applicable method, or a combination thereof.

Next, a source/drain epitaxial structure 138 is formed in the source/drain opening, as shown in FIG. 1G in accordance with some embodiments. More specifically, the source/drain epitaxial structure 138 includes a first source/drain epitaxial structure 138a formed in the source/drain opening in the first region 102a of the substrate 102, and a second epitaxial structure 138b formed in the source/drain opening in the second region 102b of the substrate 102, as shown in FIG. 1G-1 in accordance with some embodiments. The source/drain epitaxial structure 138 may be formed over opposite sides of the dummy gate structure 124. The source/drain epitaxial structure 138 may refer to a source or a drain, individually or collectively dependent upon the context.

A strained material may be grown in the source/drain opening using an epitaxial (epi) process to form the source/drain epitaxial structure 138. In addition, the lattice constant of the strained material may be different from the lattice constant of the substrate 102. The first source/drain epitaxial structure 138a may include SiGeB, SiGe, other applicable materials, or a combination thereof. The source/drain epitaxial structure 138 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method.

The first source/drain epitaxial structure 138a may be in-situ doped during the epitaxial growth process. For example, the first source/drain epitaxial structure 138a may be the epitaxially grown SiGe doped with boron (B). The first source/drain epitaxial structure 138a may be doped in one or more implantation processes after the epitaxial growth process.

Next, an isolation layer 140 is formed over the first source/drain epitaxial structure 138a and in the source/drain opening in the second region 102b of the substrate 102, as shown in FIG. 1G-1 in accordance with some embodiments. The isolation layer 140 may provide isolation between the substrate 102 and the subsequently formed source/drain epitaxial structure. The isolation layer 140 may be made of a dielectric material such as silicon nitride, silicon oxide, silicon oxynitride (SiON), other applicable materials, or a combination thereof. The isolation layer 140 may be formed by CVD, PVD, ALD, spin-on coating, or another applicable process.

Next, the second source/drain epitaxial structure 138b is formed in the source/drain opening in the second region 102b of the substrate 102, as shown in FIG. 1G-1 in accordance with some embodiments.

The second source/drain epitaxial structure 138b may include SiP, SiAs, other applicable materials, or a combination thereof. The processes for forming the second source/drain epitaxial structure 138b may be the same as, or similar to, those used to form the first source/drain epitaxial structure 138a. For the purpose of brevity, the descriptions of these processes are not repeated herein.

The second source/drain epitaxial structure 138b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features.

Next, an etch stop layer 144 may be formed over the source/drain epitaxial structure 138, as shown in FIGS. 1G and 1G-1 in accordance with some embodiments. More specifically, the etch stop layer 144 may cover the sidewalls of the gate spacer layers 136 and the top surface of the source/drain epitaxial structure 138. The etch stop layer 144 may be made of a dielectric material such as silicon nitride, silicon oxide, silicon oxynitride (SiON), other applicable materials, or a combination thereof. The etch stop layer 144 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The etch stop layer 144 may be a bi-layer structure. For example, the etch stop layer 144 may be made of silicon oxynitride (SiON) and silicon nitride. With a bi-layer etch stop layer 144, the capacitance may be reduced.

After the etch stop layer 144 is formed, an inter-layer dielectric (ILD) structure 146 is formed over the etch stop layer 144 and the source/drain epitaxial structure 138, as shown in FIGS. 1G and 1G-1 in accordance with some embodiments. In some embodiments, the ILD structure 146 surrounds the source/drain epitaxial structure 138.

The ILD structure 146 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 146 may be formed by chemical vapor deposition (CVD), physical vapor deposition (PVD), atomic layer deposition (ALD), spin-on coating, or another applicable process.

Afterwards, a planarizing process or an etch-back process may be performed on the ILD structure 146 until the top surface of the dummy gate structure 124 is exposed. After the planarizing process, the top surface of the dummy gate structure 124 may be substantially level with the top surfaces of the gate spacer layers 136 and the ILD structure 146. The planarizing process may include a grinding process, a chemical mechanical polishing (CMP) process, an etching process, other applicable processes, or a combination thereof.

Next, the first semiconductor material layers 104 may be removed and gaps may be formed between the second semiconductor material layers 106. More specifically, the second semiconductor material layers 106 exposed by the gaps form nanostructures 106, and the nanostructures 106 are configured to function as channel regions 106 in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), potassium hydroxide (KOH) solutions, or a combination thereof.

Next, gate structures 150 are formed surrounding the nanostructures 106 and over the nanostructures 106, as shown in FIGS. 1G and 1G-1 in accordance with some embodiments. Gate structures 150 are formed surrounding the nanostructures 106 to form gate-all-around (GAA) transistor structures. Therefore, the gate control ability may be enhanced.

It should be noted that, the gate structure 150 is invisible in FIG. 1G-1. The gate structure 150 is shown in dashed line to indicate the position of the gate structure 150.

In some embodiments as shown in FIGS. 1G and 1G-1, the gate structures 150 are multi-layered structures. Each of the gate structures 150 may include an interfacial layer, a gate dielectric layer 150a, a work function layer 150b, and a gate electrode layer.

The interfacial layer may be formed around the nanostructures 106 and on the exposed portions of the base fin structures. The interfacial layer may be made of silicon oxide, and the interfacial layer may be formed by thermal oxidation.

The gate dielectric layer 150a may be formed over the interfacial layer, so that the nanostructures 106 are surrounded (e.g. wrapped) by the gate dielectric layer 150a. In addition, the gate dielectric layer 150a also covers the sidewalls of the gate spacer layers 136 and the inner spacers 149 in accordance with some embodiments. The gate dielectric layer 150a may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer 150a may be formed using CVD, ALD, other applicable methods, or a combination thereof.

Next, the work function layer 150b is conformally formed over the gate dielectric layer 150a, as shown in FIGS. 1G and 1G-1 in accordance with some embodiments. The work function layer 150b may be made of a metal material. The metal material of the work function layer 150b formed in the second region 102b in the substrate 102 may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The work function layer 150b may be formed using CVD, ALD, other applicable methods, or a combination thereof.

The metal material of the work function layer 150b formed in the first region 102a in the substrate 102 may include a P-work-function metal. The P-work-function metal may include titanium nitride (TiN), tungsten nitride (WN), tantalum nitride (TaN), ruthenium (Ru), or a combination thereof. The work function layer 150b may be formed using CVD, ALD, other applicable methods, or a combination thereof.

Next, a gate electrode layer may be formed over the work function layer 150b. The gate electrode layer may be made of one or more layers of conductive material, such as aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

Next, an opening 152 may be formed in the ILD structure 146, as shown in FIGS. 1H and 1H-1 in accordance with some embodiments. A barrier layer may be conformally formed over the bottom surface and the sidewalls of the opening 152. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Next, a first spacer layer 154 is formed over the sidewalls of the ILD structure 146, as shown in FIG. 1I in accordance with some embodiments. More specifically, the first spacer layer 154 is deposited over the ILD structure 146 and the source/drain epitaxial structure 138. Afterwards, the first spacer layer 154 over the source/drain epitaxial structure 138 is etched, and the source/drain epitaxial structure 138 is exposed. The first spacer layer 154 may prevent leakage between the gate structures 150 and substantially formed contact structure.

The first spacer layer 154 may be made of SiN, SiCON, SiCO, carbon base content materials, other applicable materials, or a combination thereof. In some embodiments, the first spacer layer 154 is made of SiN. The first spacer layer 154 may be resistant to the following etching processes. The first spacer layer 154 may be formed using CVD, ALD, other applicable methods, or a combination thereof. The first spacer layer 154 may be etched by a dry etching process or a wet etching process.

Next, dopants may be implanted in the source/drain epitaxial structure 138, and an anneal process may be performed to activate the dopants. The dopants may be implanted over the top surface of the source/drain epitaxial structure 138. The dopants implanted in the first region 102a of the substrate 102 may be P-type dopant such as B, Ga, Al, In, BF3⁺ ions, or a combination thereof. The dopants implanted in the second region 102b of the substrate 102 may be N-type dopant may such as P, As, N, Sb ions, or a combination thereof. The anneal process may include a dynamic surface annealing (DSA) process, a rapid thermal annealing (RTA) process, laser anneal, furnace anneal, flash lamp anneal, other suitable annealing process, or a combination thereof.

Next, a silicide structure 156 is formed in the source/drain epitaxial structure 138, as shown in FIG. 1I in accordance with some embodiments. The silicide structure 156 may reduce the contact resistance between the source/drain epitaxial structure 138 and the subsequently formed contact structure over the source/drain epitaxial structure 138. In some embodiments, the silicide structure 156 laterally extends under the etch stop layer 144 and the ILD structure 146.

The silicide structure 156 may be made of TiSi, Ti₅Si₄, TiSi₂, NiSi, NiSi₂, CoSi, CoSi₂, WSi₂ and MoSi₂, or other suitable low-resistance materials. The silicide structure 156 may be formed over the source/drain epitaxial structure 138 by forming a metal layer over the source/drain epitaxial structure 138 first. The metal layer may react with the source/drain epitaxial structure 138 in an annealing process and a silicide layer may be produced. Afterwards, the unreacted metal layer may be removed in an etching process and the silicide structure 156 may be formed over the source/drain epitaxial structure 138.

Next, a passivation layer 158 may be formed over the silicide structure 156, as shown in FIG. 1I in accordance with some embodiments. The passivation layer 158 may prevent the silicide structure 156 from being oxidized, which may lead to higher resistance. The passivation layer 158 may be made of TiSN, other applicable materials, or a combination thereof. The passivation layer 158 may be formed by nitriding the silicide structure 156.

Afterwards, a bottom contact structure 160a is formed over the passivation layer 158, as shown in FIG. 1I in accordance with some embodiments.

The bottom contact structure 160a may be made of a metal material (e.g., Co, Ni, W, Ti, Ta, Cu, Al, Ru, Mo, TiN, TaN, or a combination thereof), metal alloys, poly-Si, other applicable conductive materials, or a combination thereof. In some embodiments, the bottom contact structure 160a is made of tungsten. The bottom contact structure 160a may be formed by a CVD process, a PVD process, an ALD process, an electroplating process, another suitable process, or a combination thereof to deposit the conductive materials of the contact structure 160. In some embodiments, the bottom contact structure 160a is formed by a PVD process.

Later, the bottom contact structure 160a is etched back, as shown in FIG. 1I in accordance with some embodiments. The sidewall of the first spacer layer 154 and the top surface of the gate structure 150 are exposed. The bottom contact structure 160a may be etched by a dry etching process or a wet etching process.

In some embodiments, the top surface of the bottom contact structure 160a is substantially level with the top surface of the source/drain epitaxial structure 138.

Next, a second spacer layer 162 is formed over the first spacer layer 154, as shown in FIG. 1J in accordance with some embodiments. More specifically, the second spacer layer 162 is deposited over the first spacer layer 154, the bottom contact structure 160a, the passivation layer 158, and the gate structure 150. Afterwards, the second spacer layer 162 over the bottom contact structure 160a is etched, and the bottom contact structure 160a is exposed. The second spacer layer 162 may determine the profile of substantially formed contact structure, and also prevent leakage between the gate structures 150 and substantially formed contact structure.

The second spacer layer 162 may be made of SiCON, SiO₂, SiCO, oxide, carbon base content materials, other applicable materials, or a combination thereof. In some embodiments, the second spacer layer 162 is made of oxide. In some embodiments, the dielectric constant of the second spacer layer 162 is in a range of about 3 to about 4. The second spacer layer 162 with lower dielectric constant may reduce the capacitance. In some embodiments, the second spacer layer 162 and the first spacer layer 154 are made of the same material.

The second spacer layer 162 may be formed using CVD, ALD, other applicable methods, or a combination thereof. The second spacer layer 162 may be etched by a dry etching process or a wet etching process.

In some embodiments, the first spacer layer 154 and the second spacer layer 162 have different thicknesses. The ratio of the thickness of the second spacer layer 162 and the thickness of the first spacer layer 154 is in a range of about 10:1 to about 1:1. If the first spacer layer 154 is too thick, the capacitance may be too great. If the first spacer layer 154 is too thin, it may be etched through in the subsequent etching process, and there may be leakage between the gate structure 150 and the substantially formed contact structure.

When etching the second spacer layer 162, the bottom contact structure 160a is also etched, and a recess 164 is formed, as shown in FIG. 1J in accordance with some embodiments. In some embodiments, the top surface of the middle portion of the bottom contact structure 160a is lower than the top surface of the side portions of the bottom contact structure 160a.

Next, an upper contact structure 160b is formed in the opening 152 over the bottom contact structure 160a, as shown in FIG. 1K in accordance with some embodiments. In some embodiments, the top surface of the upper contact structure 160b is lower than the top surface of the second spacer layer 162.

The upper contact structure 160b may be made of a metal material (e.g., Co, Ni, W, Ti, Ta, Cu, Al, Ru, Mo, TiN, TaN, or a combination thereof), metal alloys, poly-Si, other applicable conductive materials, or a combination thereof. In some embodiments, the upper contact structure 160b is made of fluorine-free tungsten. The upper contact structure 160b may be formed by a CVD process, a PVD process, an ALD process, an electroplating process, another suitable process, or a combination thereof to deposit the conductive materials of the contact structure 160. In some embodiments, the upper contact structure 160b is formed by a CVD process.

Since the bottom contact structure 160a and the upper contact structure 160b may be formed of the same material, the boundary between the bottom contact structure 160a and the upper contact structure 160b is shown dashed line, as shown in FIG. 1K in accordance with some embodiments.

Later, a top contact structure 160c is formed in the opening 152 over the upper contact structure 160b, as shown in FIG. 1L in accordance with some embodiments.

The top contact structure 160c may be made of a metal material (e.g., Co, Ni, W, Ti, Ta, Cu, Al, Ru, Mo, TiN, TaN, or a combination thereof), metal alloys, poly-Si, other applicable conductive materials, or a combination thereof. The top contact structure 160c may be formed by a CVD process, a PVD process, an ALD process, an electroplating process, another suitable process, or a combination thereof to deposit the conductive materials of the contact structure 160.

In some embodiments, the bottom contact structure 160a wrapped in the silicide structure 156 and the upper contact structure 160b and the top contact structure 160c wrapped in the first spacer layer 154 have different widths.

The width of the bottom contact structure 160a may be determined by the thickness of the first spacer layer 154. The widths of the upper contact structure 160b and the top contact structure 160c may be determined by the thickness of the second spacer layer 162 and the first spacer layer 154. In some embodiments, the bottom contact structure 160a is wider than the upper contact structure 160b and the top contact structure 160c. With wider bottom contact structure 160a, the silicide structure 156 may be larger, and the resistance may be lowered. With narrower upper contact structure 160b and top contact structure 160c, the capacitance may be lowered. The profile of the contact structure 160 may be achieved by modifying the thickness of the second spacer layer 162 and the first spacer layer 154.

Afterwards, a planarization process such as a chemical mechanical polishing (CMP) process or an etch back process is optionally performed to remove excess conductive materials. After the planarization process, the top surface of the contact structure 160 may be level with the top surface of the gate spacer layers 136.

Since the top contact structure 160c and the upper contact structure 160b may be formed of the same material, the boundary between the top contact structure 160c and the upper contact structure 160b is shown dashed line, as shown in FIG. 1L in accordance with some embodiments.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered.

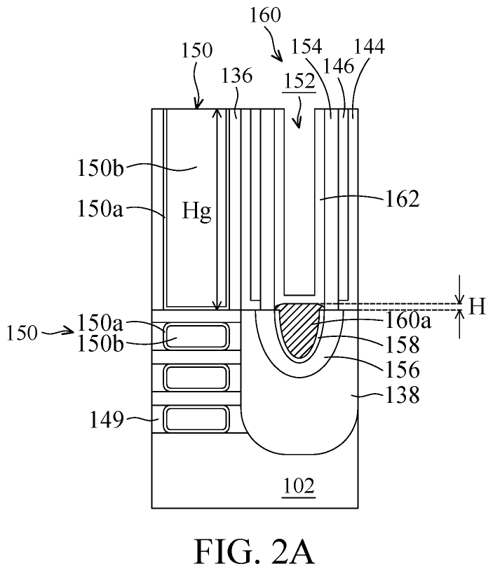

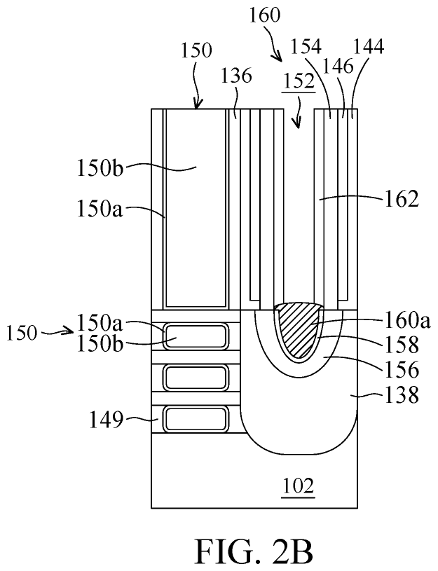

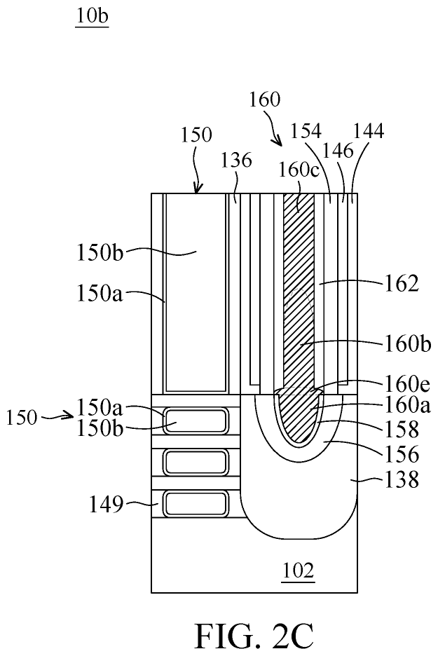

Many variations and/or modifications may be made to the embodiments of the disclosure. FIGS. 2A-2C are cross-sectional representations of various stages of forming a semiconductor device structure 10b. Some processes or devices are the same as, or similar to, those described in the embodiments above, and therefore the descriptions of these processes and devices are not repeated herein. The difference from the embodiments described above is that, as shown in FIG. 2A in accordance with some embodiments, the top surface of the bottom contact structure 160a is higher than the top surface of the silicide structure 156.

In some embodiments, the bottom contact structure 160a covers the top surface of the passivation layer 158. Later, the second spacer layer 162 is deposited over the bottom contact structure 160a and the first spacer layer 154, as shown in FIG. 2A in accordance with some embodiments.

In some embodiments, the top surface of the bottom contact structure 160a is higher than the top surface of the silicide structure 156 by a height H. In some embodiments, the ratio of the height H and the height of the gate structure Hg is in a range of about 0 to about 0.5. If the ratio of the height H and the height of the gate structure Hg is too less, the second spacer layer 162 may cause higher resistance. If the ratio of the height H and the height of the gate structure Hg is too high, the gate structure 150 and the contact structure 160 may be too close, and the capacitance may be increased

In some embodiments, the bottom contact structure 160a is in direct contact with the first spacer layer 154.

Afterwards, the second spacer layer 162 formed over the bottom contact structure 160a is etched, and the bottom contact structure 160a is exposed, as shown in FIG. 2B in accordance with some embodiments. In some embodiments, the second spacer layer 162 is separated from the silicide structure 156. The risk of increasing resistance may be prevented.

Afterwards, the upper contact structure 160b and the top contact structure 160c is formed over the bottom contact structure 160a, as shown in FIG. 2C in accordance with some embodiments.

In some embodiments, the extending portion 160a of the contact structure 160 is sandwiched between the bottom contact structure 160a and the upper contact structure 160b. In some embodiments, the extending portion 160a of the contact structure 160 is wider than the upper contact structure 160b and the upper contact structure 160b.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered. With the contact structure 160 separating the second spacer layer 162 and the passivation layer 158, the resistance may not be increased.

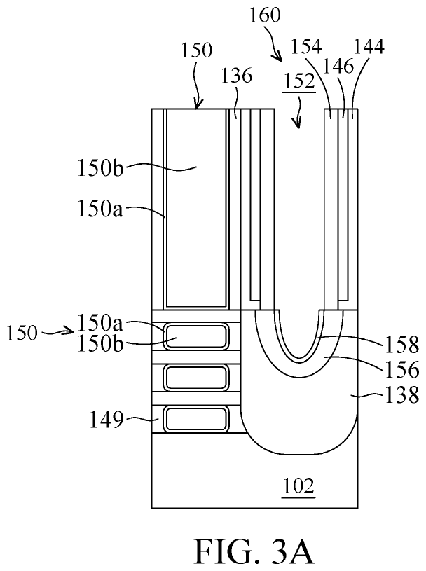

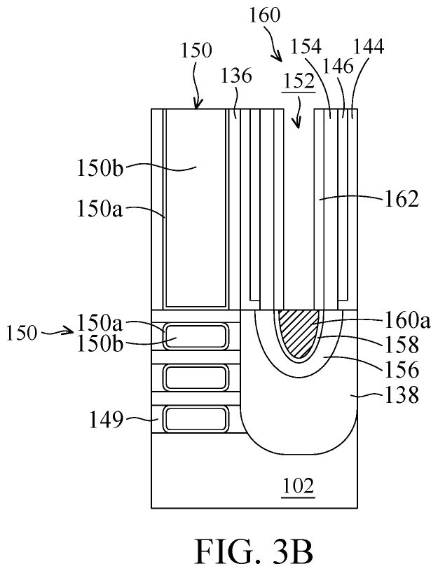

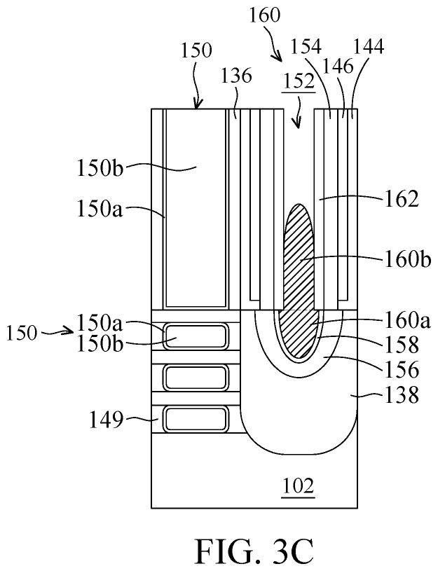

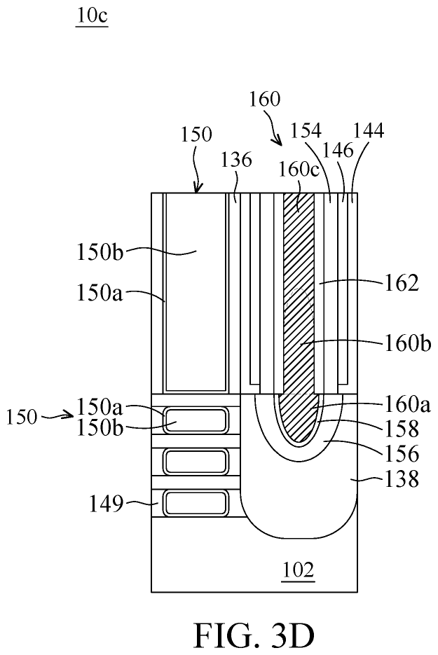

Many variations and/or modifications may be made to the embodiments of the disclosure. FIGS. 3A-3D are cross-sectional representations of various stages of forming a semiconductor device structure 10c. Some processes or devices are the same as, or similar to, those described in the embodiments above, and therefore the descriptions of these processes and devices are not repeated herein. The difference from the embodiments described above is that, as shown in FIG. 3B in accordance with some embodiments, the bottom contact structure 160a is not recessed after etching the second spacer layer 162.

After forming the silicide structure 156, the bottom contact structure 160a is formed in in the opening 152. After conformally depositing the second spacer layer 162, the second spacer layer 162 formed over the bottom contact structure 160a is removed, as shown in FIGS. 3A-3B in accordance with some embodiments.

In some embodiments, the top surface of the middle portion of the bottom contact structure 160a is substantially level with the top surface of the side portions of the bottom contact structure 160a after etching the second spacer layer 162. In some embodiments, the top surface of the bottom contact structure 160a is substantially level with the bottom surface of the second spacer layer 162 after etching the second spacer layer 162.

Later, the upper contact structure 160b and the top contact structure 160c is formed over the bottom contact structure 160a, as shown in FIGS. 3C-3D in accordance with some embodiments.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered. The bottom contact structure 160a may not be recessed after etching the second spacer layer 162.

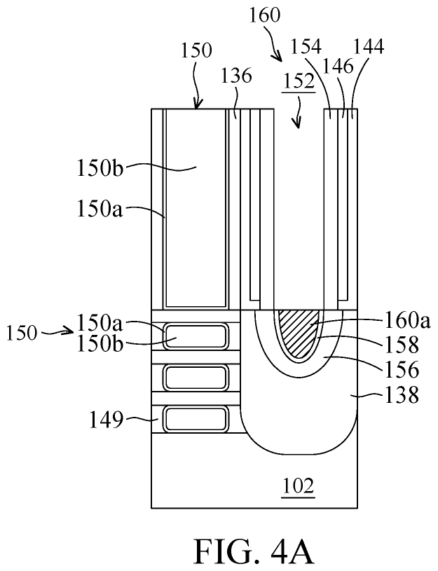

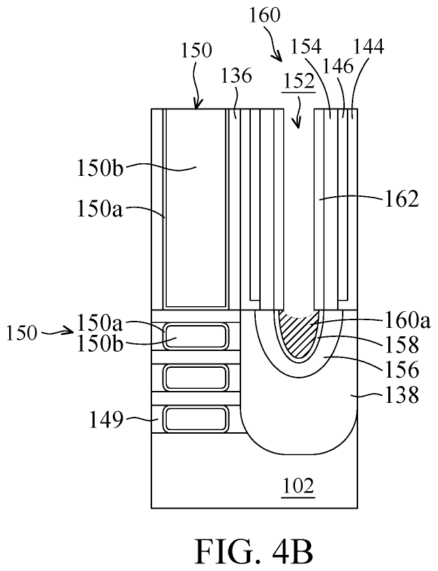

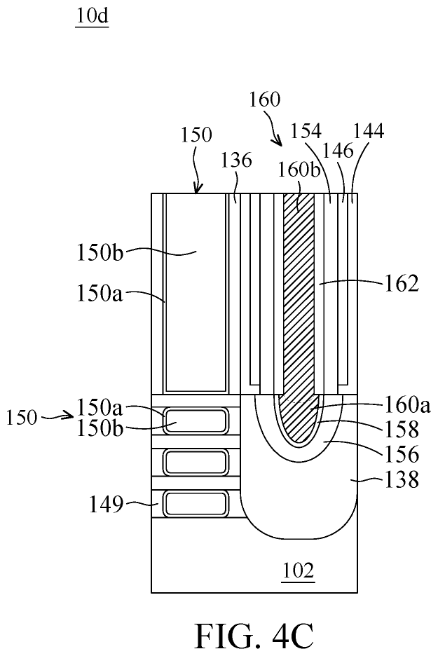

Many variations and/or modifications may be made to the embodiments of the disclosure. FIGS. 4A-4C are cross-sectional representations of various stages of forming a semiconductor device structure 10d. Some processes or devices are the same as, or similar to, those described in the embodiments above, and therefore the descriptions of these processes and devices are not repeated herein. The difference from the embodiments described above is that, as shown in FIG. 4C in accordance with some embodiments, the upper contact structure 160b fills up the opening 152.

After forming the second spacer layer 162, the bottom contact structure 160a is formed in the opening 152. Afterwards, the upper contact structure 160b is formed over the bottom contact structure 160a in the opening 152. A planarization process such as a chemical mechanical polishing (CMP) process or an etch back process is optionally performed to remove excess conductive materials. After the planarization process, the top surface of the upper contact structure 160b may be level with the top surface of the gate spacer layers 136. The process may be simplified by filling up the opening 152 with the upper contact structure 160b.

By forming separate second spacer layer 162 and the first spacer layer 154 over sidewalls of the ILD structure 146, the profile of the contact structure 160 may be modified. With wider silicide structure 156, the resistance may be lowered. With narrower upper contact structure 160b, the capacitance may be lowered. The upper contact structure 160b may fill up the opening 152 and the process may be simplified.

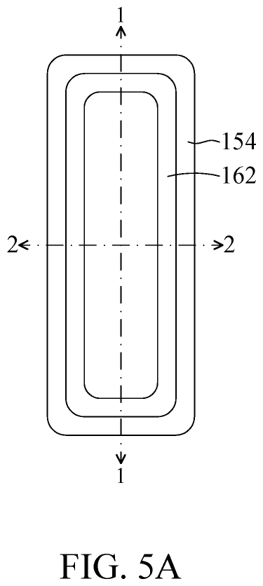

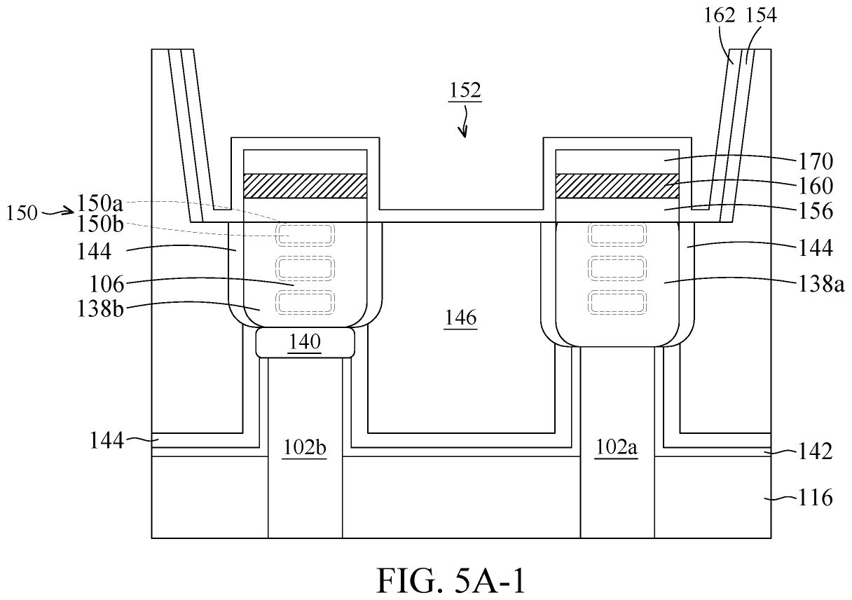

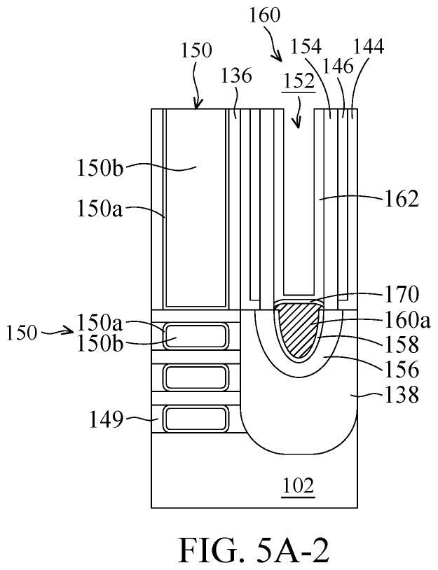

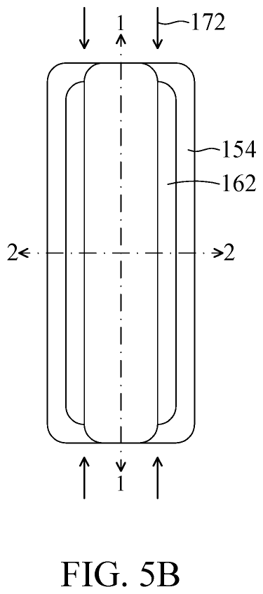

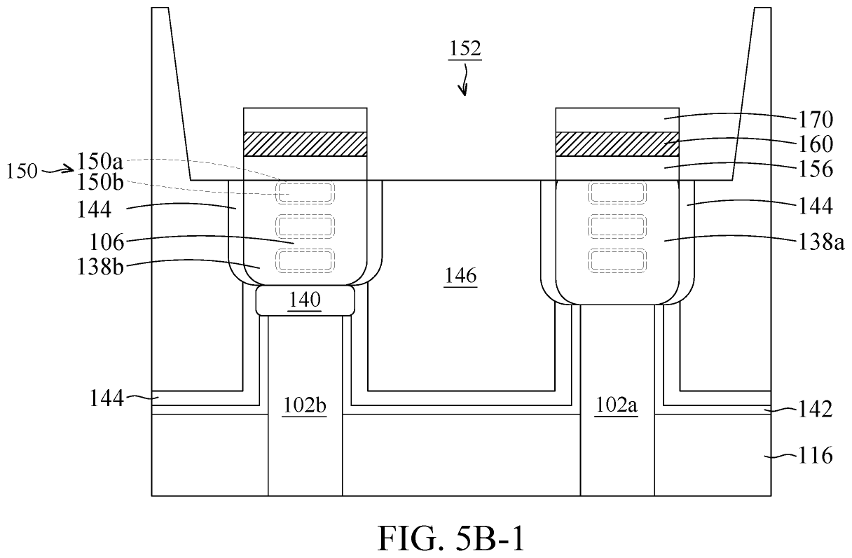

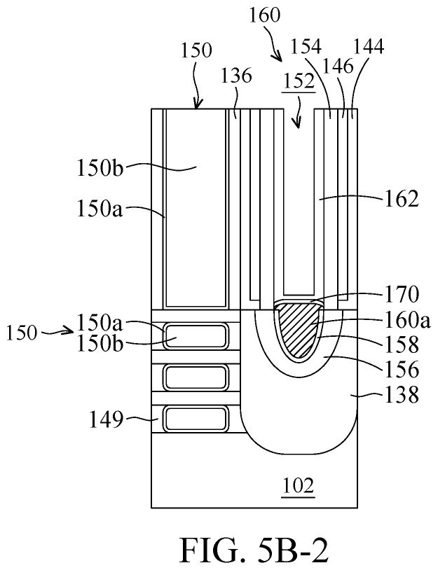

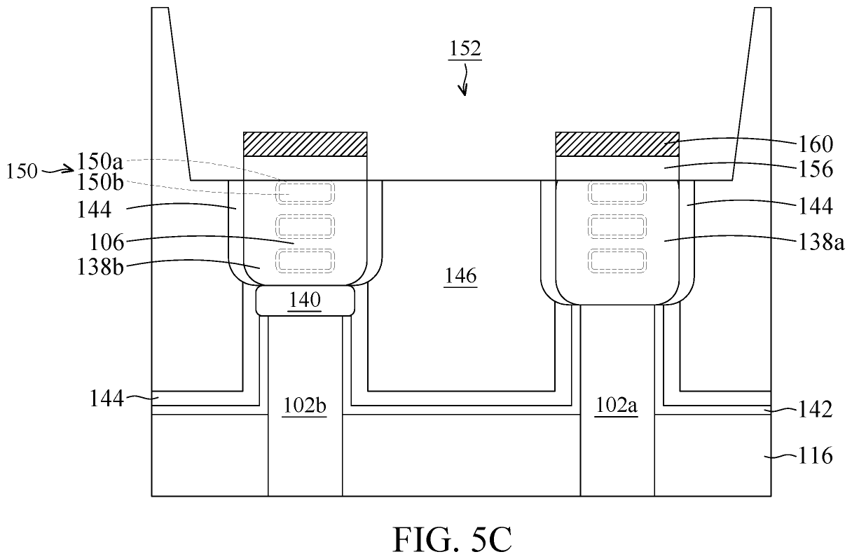

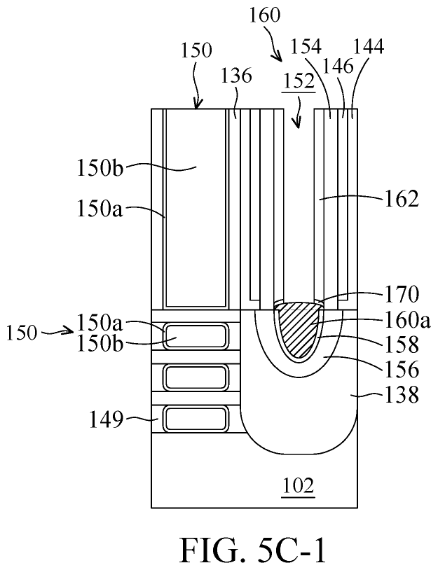

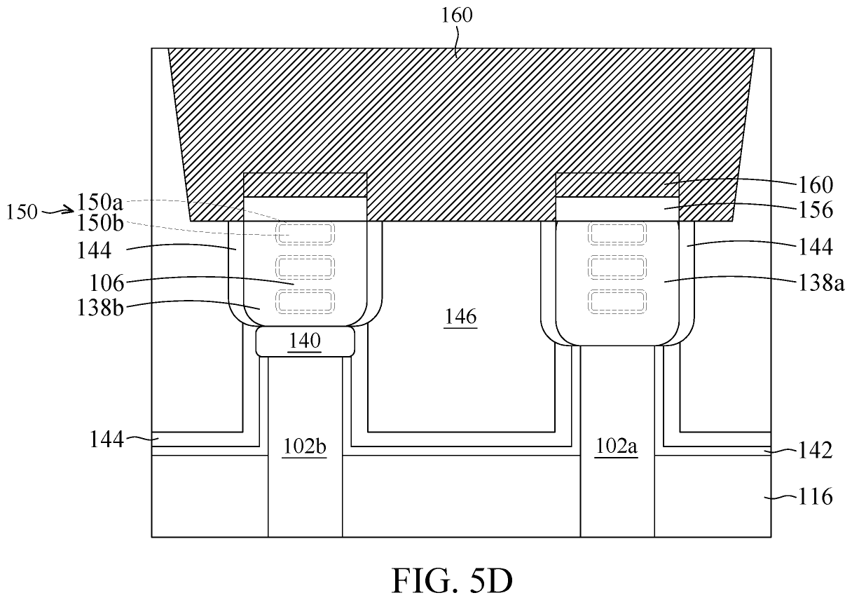

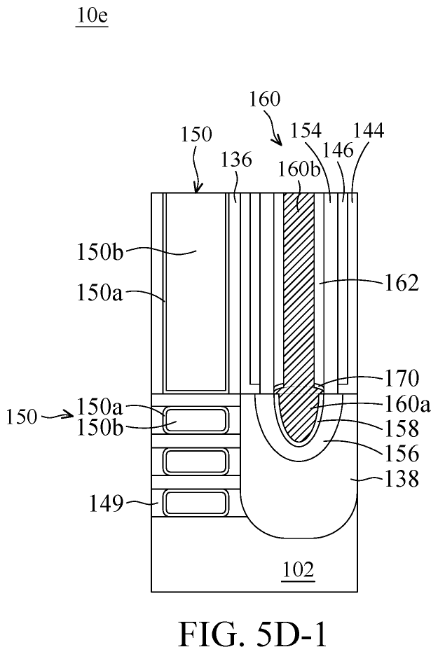

Many variations and/or modifications may be made to the embodiments of the disclosure. FIGS. 5A, 5B are top views of various stages of forming a semiconductor device structure 10e, and FIGS. 5A-1, 5A-2, 5B-1, 5B-2, 5C, 5C-1, 5D, 5D-1 are cross-sectional representations of various stages of forming a semiconductor device structure 10e, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 5B in accordance with some embodiments, an implantation process 172 is performed after the second spacer layer 162 is deposited.

FIGS. 5A-1 show cross-sectional representations taken along line 1-1 in FIG. 5A. FIGS. 5A-2 show cross-sectional representations taken along line 2-2 in FIG. 5A.

After forming the contact structure 160, a protection layer 170 may be formed over the contact structure 160, as shown in FIGS. 5A-1 and 5A-2 in accordance with some embodiments. The protection layer 170 may be formed by oxidizing the contact structure 160. In some embodiments, the protection layer 170 is made of tungsten oxide.

In some embodiments, the first spacer layer 154 is formed over the sidewalls of the ILD structure 146, and the second spacer layer 162 is conformally formed over the first spacer layer 154, the ILD structure 146, and the source/drain epitaxial structure 138.

Next, an implantation process 172 is performed in the direction along line 1-1 in FIG. 5B. In the implantation process 172, dopants may implanted over the sidewalls of the ILD structure 146 in the opening 152 to remove the first spacer layer 154 and the second spacer layer 162 formed over the sidewalls of the ILD structure 146. The first spacer layer 154 and the second spacer layer 162 may be etched after the implantation process 172, as shown in FIGS. 5B and 5B-1 accordance with some embodiments. The area of subsequently formed contact structure may be enlarged. It may be easier to form other contact structure thereon. The dopants used in the implantation process 172 may include Ar, Xe, other applicable heavy elements, or a combination thereof. In some embodiments, the dopants are implanted in a tilt angle.

Afterwards, the second spacer layer 162 formed over the bottom contact structure 160a is removed, as shown in FIG. 5C-1 accordance with some embodiments. The protection layer 170 is also removed, as shown in FIG. 5C accordance with some embodiments. Later, the contact structure 160 is formed in the opening 152, as shown in FIGS. 5D and 5D-1 in accordance with some embodiments. In some embodiments, the ILD structure 146 is in direct contact with the contact structure 160.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered. An implantation process 172 may be performed to remove the first spacer layer 154 and the second spacer layer 162 in the direction parallel with the gate structure 150. The area of the contact structure 160 may be enlarged, and it may be easier for other contact structures to form thereon.

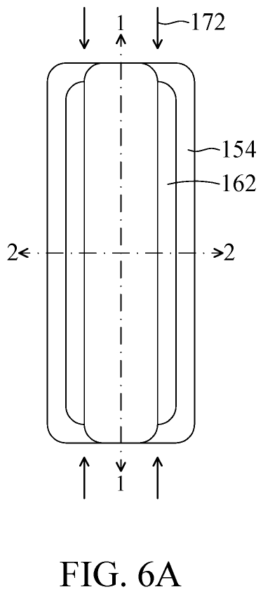

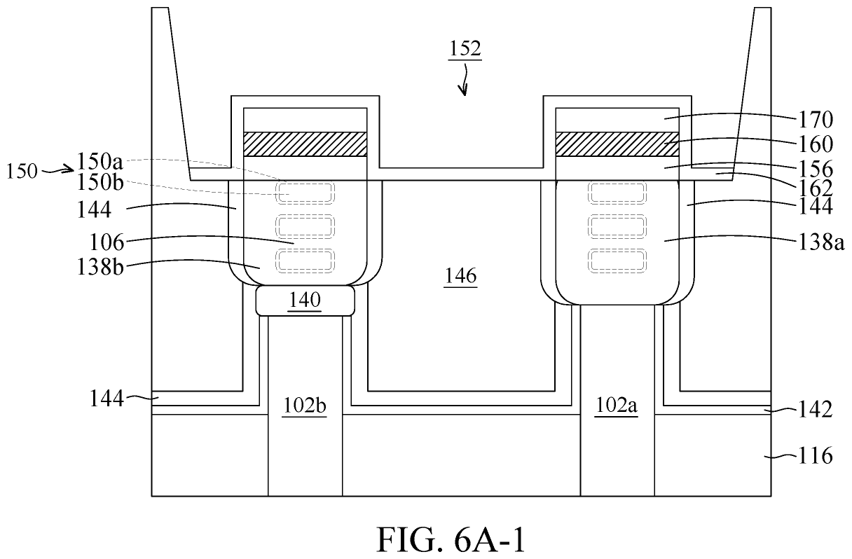

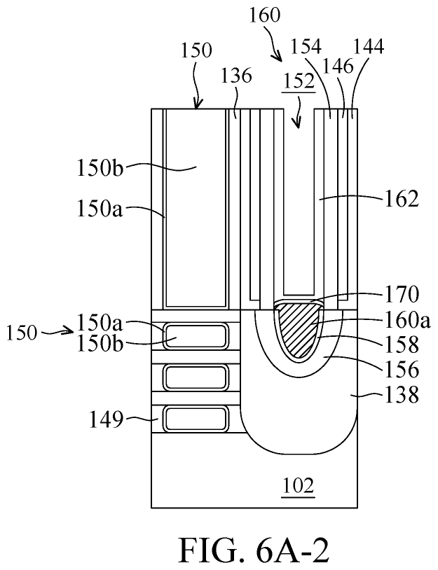

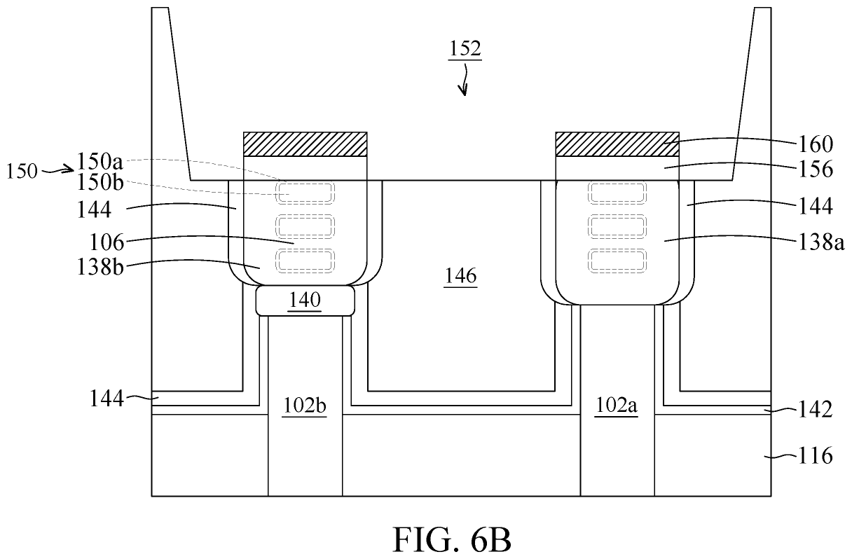

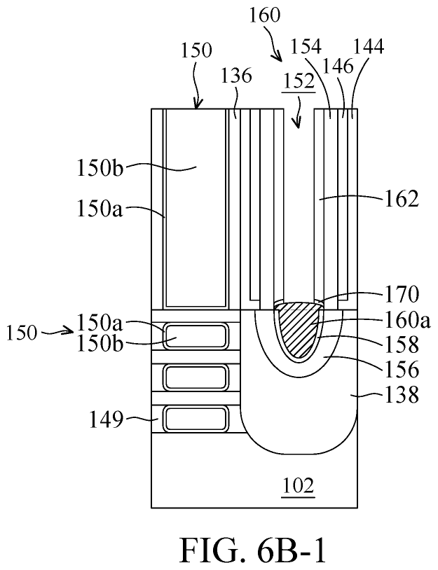

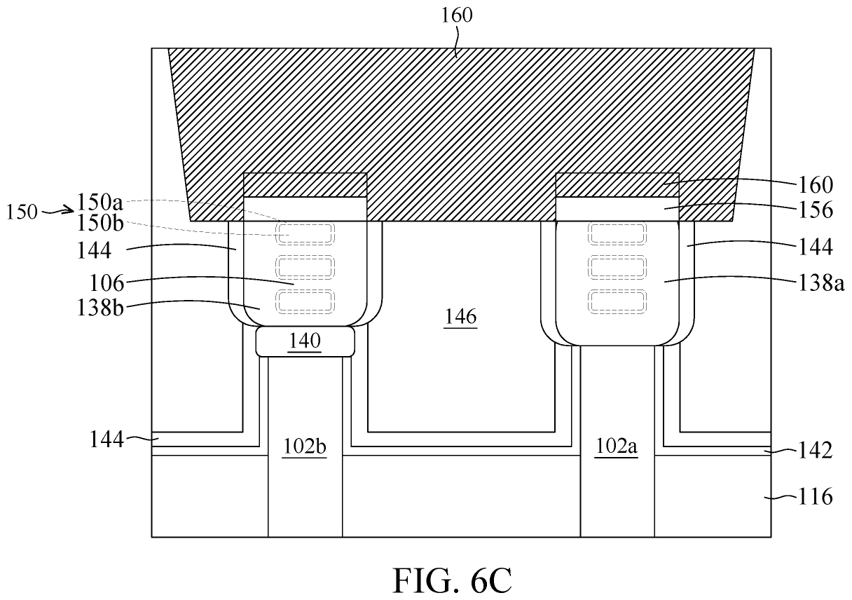

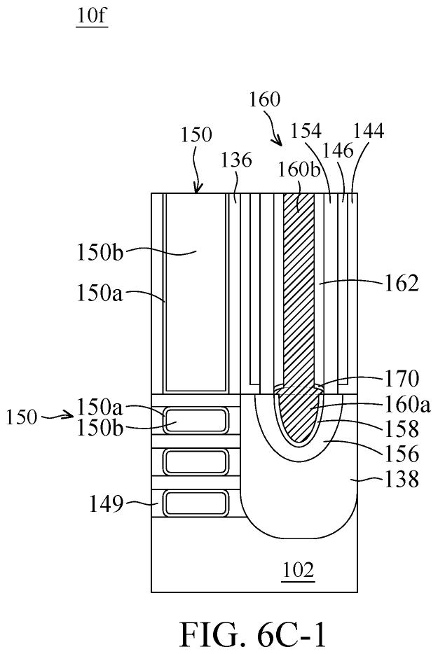

Many variations and/or modifications may be made to the embodiments of the disclosure. FIG. 6A is a top view of forming a semiconductor device structure 10f, and FIGS. 6A-1, 6A-2, 6B, 6B-1, 6C, 6C-1 are cross-sectional representations of various stages of forming a semiconductor device structure 10f, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 6A-1 in accordance with some embodiments, the second spacer layer 162 remains over the source/drain epitaxial structure 138 after the implantation process 172 implanting the dopants over the sidewalls of the ILD structure 146.

The implantation process 172 only removes the first spacer layer 154 and the second spacer layer 162 over the sidewalls of the ILD structure 146, and the second spacer layer 162 over the source/drain epitaxial structure 138 remains, as shown in FIGS. 6A and 6A-1 in accordance with some embodiments. Afterwards, the second spacer layer 162 and the protection layer 170 formed over the source/drain epitaxial structure 138 are removed, as shown in FIGS. 6B and 6B-1 in accordance with some embodiments. Later, the contact structure 160 is formed in the opening 152, as shown in FIGS. 6C and 6C-1 in accordance with some embodiments.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered. An implantation process 172 may be performed to remove the first spacer layer 154 and the second spacer layer 162 in the direction parallel with the gate structure 150. The area of the contact structure 160 may be enlarged, and it may be easier for other contact structures to form thereon. The second spacer layer 162 may remain over the source/drain epitaxial structure 138 after the implantation process 172.

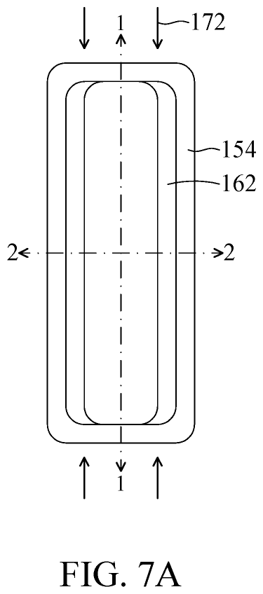

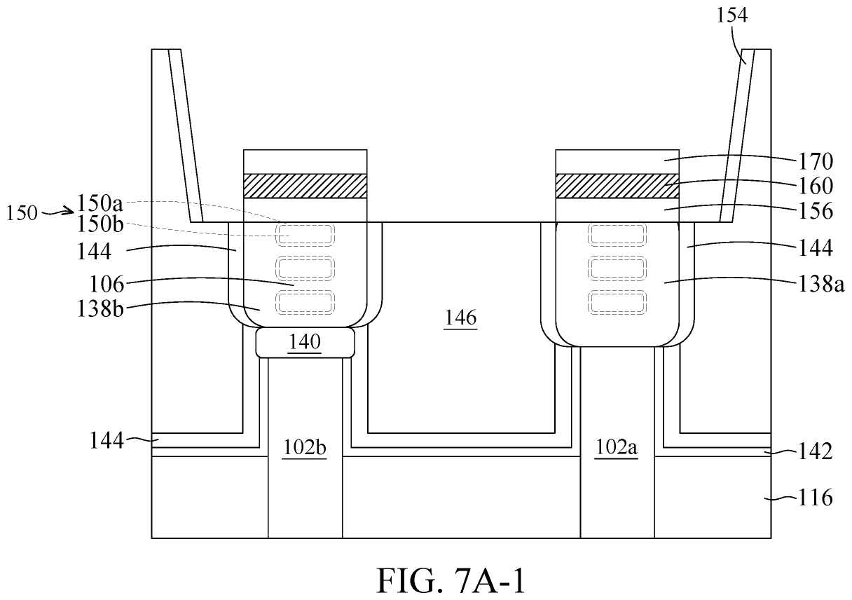

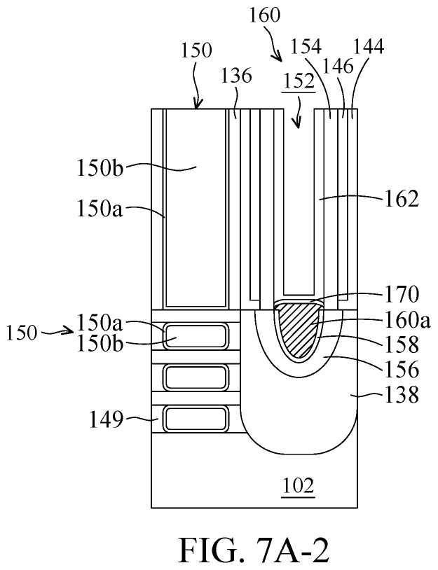

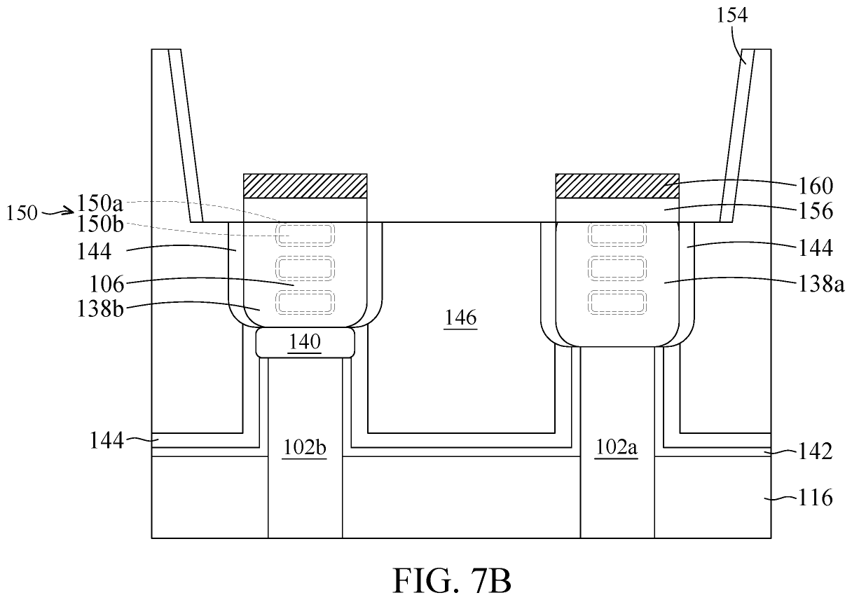

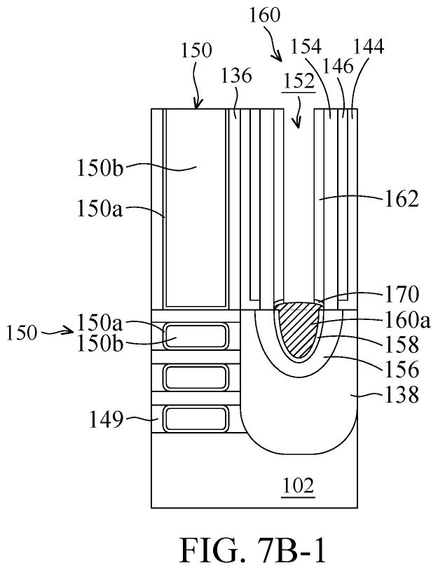

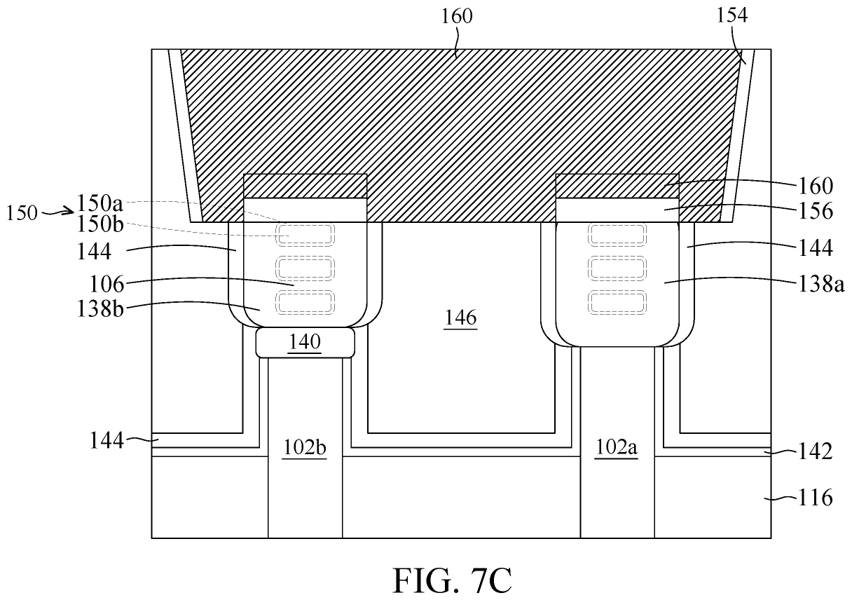

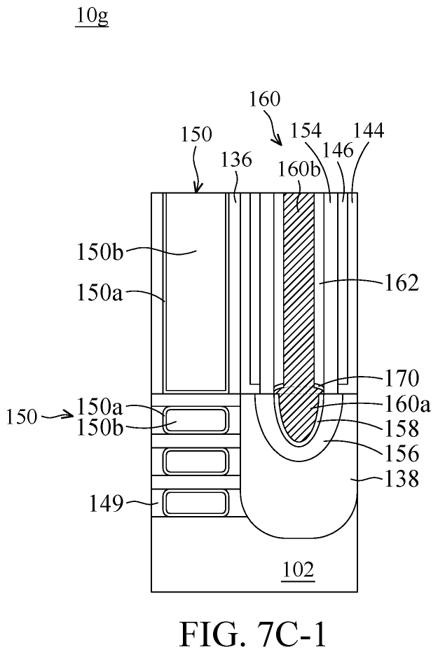

Many variations and/or modifications may be made to the embodiments of the disclosure. FIG. 7A is a top view of forming a semiconductor device structure 10g, and FIGS. 7A-1, 7A-2, 7B, 7B-1, 7C, 7C-1 are cross-sectional representations of various stages of forming a semiconductor device structure 10g, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 7A and 7A-1 in accordance with some embodiments, the first spacer layer 154 remains over the sidewalls of the ILD structure 146 after the implantation process 172 implanting the dopants over the sidewalls of the ILD structure 146.

With the first spacer layer 154 remains over sidewalls of the ILD structure 146, the space between adjacent substantially formed contact structures may be enlarged, and the adjacent substantially formed contact structures may not be short-circuited.

Afterwards, the protection layer 170 formed over the source/drain epitaxial structure 138 is removed, as shown in FIGS. 7B and 7B-1 in accordance with some embodiments. Later, the contact structure 160 is formed in the opening 152, as shown in FIGS. 7C and 7C-1 in accordance with some embodiments.

By forming separate second spacer layer 162 and the first spacer layer 154 over sidewalls of the ILD structure 146, the profile of the contact structure 160 may be modified. With wider silicide structure 156, the resistance may be lowered. With narrower top contact structure 160c, the capacitance may be lowered. An implantation process 172 may be performed to remove the first spacer layer 154 and the second spacer layer 162 in the direction parallel with the gate structure 150. The area of the contact structure 160 may be enlarged, and it may be easier for other contact structures to form thereon. The first spacer layer 154 may remain over sidewalls of the ILD structure 146 after the implantation process 172, and the adjacent substantially formed contact structures may not be short-circuited.

As described previously, the contact structure 160 is modified by forming the first spacer layer 154 and the second spacer layer 162. With wider bottom contact structure 160a, the silicide structure 156 may be larger, and the resistance may be lowered. With narrower upper contact structure 160b, the capacitance may be lowered. In some embodiments as shown in FIG. 2, the contact structure 160 is formed between the second spacer layer 162 and the silicide structure 156, and the risk of increasing resistance is prevented. In some embodiments as shown in FIG. 3, the bottom contact structure 160a is not recessed when forming the second spacer layer 162. In some embodiments as shown in FIG. 4, the upper contact structure 160b fills up the opening 152. In some embodiments as shown in FIG. 5, an implantation process 172 is performed to remove the first spacer layer 154 and the second spacer layer 162 over the sidewalls of the ILD structure 146. The contact structure 160 is enlarged, and forming other contact structure thereon is easier. In some embodiments as shown in FIG. 6, the second spacer layer 162 remains over the source/drain epitaxial structure 138 after the implantation process. In some embodiments as shown in FIG. 7, the first spacer layer 154 remains over the sidewalls of the ILD structure 146 after the implantation process. The adjacent substantially formed contact structures are not short-circuited.

Embodiments of a semiconductor device structure and a method for forming the same are provided. The profile of contact structure may be modified by forming multiple spacer layers. Larger silicide structure may reduce the resistance. Narrower upper contact structure may reduce the capacitance.

In some embodiments, a method for forming a semiconductor device structure is provided. The method for forming a semiconductor device structure includes forming nanostructures over a substrate. The method for forming a semiconductor device structure also includes forming a gate structure wrapped around the nanostructures. The method for forming a semiconductor device structure also includes forming source/drain epitaxial structures over opposite sides of the nanostructures. The method for forming a semiconductor device structure also includes forming an interlayer dielectric structure over the source/drain epitaxial structures. The method for forming a semiconductor device structure also includes etching the interlayer dielectric structure to form an opening exposing the source/drain epitaxial structures. The method for forming a semiconductor device structure also includes depositing a first spacer layer over sidewalls of the interlayer dielectric structure in the opening. The method for forming a semiconductor device structure also includes forming a silicide structure over the source/drain epitaxial structures. The method for forming a semiconductor device structure also includes forming a bottom contact structure over the silicide structure. The method for forming a semiconductor device structure also includes depositing a second spacer layer over the first spacer layer. The method for forming a semiconductor device structure also includes forming an upper contact structure over the first contact structure.

In some embodiments, a method for forming a semiconductor device structure is provided. The method for forming a semiconductor device structure includes forming a fin structure extending in a first direction over a substrate. The method for forming a semiconductor device structure also includes forming a gate structure across the fin structure, wherein the gate structure extends in a second direction. The second direction is perpendicular to the first direction. The method for forming a semiconductor device structure also includes forming source/drain epitaxial structures over opposite sides of the gate structure. The method for forming a semiconductor device structure also includes forming a silicide structure over the source/drain epitaxial structures. The method for forming a semiconductor device structure also includes forming a passivation layer over the silicide structure. The method for forming a semiconductor device structure also includes forming a bottom contact structure over the passivation layer. The method for forming a semiconductor device structure also includes depositing a second spacer layer over the bottom contact structure and the passivation layer. The method for forming a semiconductor device structure also includes etching the second spacer layer over the bottom contact structure. The method for forming a semiconductor device structure also includes forming an upper contact structure over the bottom contact structure. The method for forming a semiconductor device structure also includes forming a top contact structure over the upper contact structure.

In some embodiments, a semiconductor device structure is provided. The semiconductor device structure includes nanostructures formed over a substrate. The semiconductor device structure also includes a gate structure wrapped around the nanostructures. The semiconductor device structure also includes source/drain epitaxial structures formed over opposite sides of the nanostructures. The semiconductor device structure also includes a silicide structure formed over the source/drain epitaxial structures. The semiconductor device structure also includes a first spacer layer formed over the silicide structure. The semiconductor device structure also includes a contact structure wrapped by the silicide structure and the first spacer layer. A bottom portion of the contact structure wrapped by the silicide structure and an upper portion of the contact structure wrapped by the first spacer layer have different widths.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming nanostructures over a substrate;
forming a gate structure wrapped around the nanostructures;
forming source/drain epitaxial structures over opposite sides of the nanostructures;
forming an interlayer dielectric structure over the source/drain epitaxial structures;
etching the interlayer dielectric structure to form an opening exposing the source/drain epitaxial structures;
depositing a first spacer layer over sidewalls of the interlayer dielectric structure in the opening;
forming a silicide structure over the source/drain epitaxial structures;
forming a bottom contact structure over the silicide structure;
depositing a second spacer layer over the first spacer layer; and
forming an upper contact structure over the first contact structure.

2. The method for forming the semiconductor device structure as claimed in claim 1, wherein the bottom contact structure is in direct contact with the first spacer layer.

3. The method for forming the semiconductor device structure as claimed in claim 1, further comprising:
removing the second spacer layer formed over the bottom contact structure,
wherein the bottom contact structure is recessed after removing the second spacer layer.

4. The method for forming the semiconductor device structure as claimed in claim 1, further comprising:
implanting dopants over the sidewalls of the interlayer dielectric structure in the opening to remove the second spacer layer formed over the sidewalls of the interlayer dielectric structure.

5. The method for forming the semiconductor device structure as claimed in claim 4, wherein the second spacer layer remains over the source/drain epitaxial structures after implanting the dopants over the sidewalls of the interlayer dielectric structure.

6. The method for forming the semiconductor device structure as claimed in claim 4, wherein the first spacer layer remains over the sidewalls of the interlayer dielectric structure after the dopants are implanted over the sidewalls of the interlayer dielectric structure.

7. The method for forming the semiconductor device structure as claimed in claim 4, wherein the first spacer layer is removed while implanting the dopants over the sidewalls of the interlayer dielectric structure.

8. The method for forming the semiconductor device structure as claimed in claim 1, further comprising:
forming a top contact structure over the upper contact structure in the opening.

9. A method for forming a semiconductor device structure, comprising:
forming a fin structure extending in a first direction over a substrate;
forming a gate structure across the fin structure, wherein the gate structure extends in a second direction perpendicular to the first direction;
forming source/drain epitaxial structures over opposite sides of the gate structure;
forming a silicide structure over the source/drain epitaxial structures;
forming a passivation layer over the silicide structure;
forming a bottom contact structure over the passivation layer;
depositing a second spacer layer over the bottom contact structure and the passivation layer;
etching the second spacer layer over the bottom contact structure;
forming an upper contact structure over the bottom contact structure; and
forming a top contact structure over the upper contact structure.

10. The method for forming the semiconductor device structure as claimed in claim 9, wherein a top surface of the bottom contact structure is substantially level with a bottom surface of the second spacer layer after etching the second spacer layer.

11. The method for forming the semiconductor device structure as claimed in claim 9, further comprising:
implanting dopants in the second direction after depositing the second spacer layer.

12. The method for forming the semiconductor device structure as claimed in claim 11, wherein implanting the dopants comprises implanting Ar, Xe, or a combination thereof.

13. The method for forming the semiconductor device structure as claimed in claim 11, wherein the second spacer layer is etched after implanting the dopants.

14. The method for forming the semiconductor device structure as claimed in claim 9, wherein the fin structure protrudes over the substrate in a third direction, and the dopants are implanted at a direction different from the third direction.

15. A semiconductor device structure, comprising:
nanostructures formed over a substrate;
a gate structure wrapped around the nanostructures;
source/drain epitaxial structures formed over opposite sides of the nanostructures;
a silicide structure formed over the source/drain epitaxial structures;
a first spacer layer formed over the silicide structure;
a contact structure wrapped in the silicide structure and the first spacer layer,
wherein a bottom portion of the contact structure wrapped in the silicide structure and an upper portion of the contact structure wrapped by the first spacer layer have different widths.

16. The semiconductor device structure as claimed in claim 15, further comprising:
a passivation layer formed over the silicide structure.

17. The semiconductor device structure as claimed in claim 15, further comprising:
an extending portion of the contact structure sandwiched between the bottom portion and the upper portion of the contact structure,
wherein the extending portion of the contact structure is wider than the upper portion of the contact structure.

18. The semiconductor device structure as claimed in claim 15, further comprising:
a second spacer layer formed over the first spacer layer.

19. The semiconductor device structure as claimed in claim 18, wherein the first spacer layer and the second spacer layer have different thicknesses.

20. The semiconductor device structure as claimed in claim 15, further comprising:
an interlayer dielectric structure formed over the source/drain epitaxial structures,
wherein the interlayer dielectric structure is in direct contact with the contact structure.
